(19) United States
(12) Patent Application Publication
(10) Pub. No.: US 2020/0066510 A1
(43) Pub. Date: Feb. 27, 2020

(54) SUBSTRATE PROCESSING DEVICE, SUBSTRATE PROCESSING METHOD, AND STORAGE MEDIUM STORING PROGRAM FOR CAUSING COMPUTER TO EXECUTE METHOD FOR CONTROLLING SUBSTRATE PROCESSING DEVICE

(71) Applicant: EBARA CORPORATION, Tokyo (JP)

(72) Inventors: Satoru Yamamoto, Tokyo (JP); Yu Machida, Tokyo (JP)

(21) Appl. No.: 16/547,922

(22) Filed: Aug. 22, 2019

(30) Foreign Application Priority Data
Aug. 24, 2018 (JP) 157288/2018

(51) Int. Cl. H01L 21/02; B08B 1/02

(52) U.S. Cl. CPC H01L 21/02087; B08B 1/02

(57) ABSTRACT

There is provided a substrate processing device. This substrate processing device includes a substrate holder that holds and rotates a substrate, a first processing head that processes a first plane of the substrate held on the substrate holder, and a second processing head that processes a peripheral portion of the substrate held on the substrate holder.

### TECHNICAL FIELD

### Cross-Reference to Related Application

This application is based upon and claims benefit of priority from Japanese Patent Application No. 2018-157288 filed on Aug. 24, 2018, the entire contents of which are incorporated herein by reference.

The present invention relates to a substrate processing device, a substrate processing method, and a storage medium storing a program for causing a computer to execute a method for controlling the substrate processing device.

### Background Art

Recently, devices such as a memory circuit, a logic circuit, and an image sensor (for example, a CMOS sensor) have been more highly integrated. In a process for forming these devices, foreign objects such as microparticles and dust may be attached to the device. The foreign objects attached to the device may cause short circuit between wirings and trouble in the circuit. Accordingly, to improve reliability of the device, it is necessary to clean a wafer on which the device has been formed to remove the foreign objects on the wafer.

The foreign objects such as the microparticles and the dust as described above may be also attached to a back surface (a non-device surface) of the wafer. When such foreign objects are attached to the back surface of the wafer, the wafer separates from a stage reference surface of an exposure device, or a wafer surface is inclined with respect to the stage reference surface. As a result, deviation in patterning or deviation in focal distance may occur. To reduce such a problem, it is necessary to remove the foreign objects attached to the back surface of the wafer.

Nowadays, a patterning device using a nanoimprint technology besides an optical exposure technology has been developed. This nanoimprint technology is a technology that presses a mold for patterning to resin material applied to the wafer to transfer a wiring pattern. In the nanoimprint technology, to avoid dirt transfer between the mold and the wafer and between the wafer and the wafer, it is necessary to remove the foreign objects that exist on the surface of the wafer. Therefore, a device that supports the wafer from below with a high pressure fluid and brings a polishing tool into sliding contact with the wafer with a high load to slightly scrape off the surface of the wafer has been proposed.

When a front surface or the back surface of the wafer is processed, polishing or cleaning of the wafer is performed while a substrate rotation mechanism rotates the wafer. At this time, when a substrate is rotated by rotating a chuck that grips a peripheral portion of the wafer, a head that cleans or polishes the wafer and the chuck interfere with one another. In view of this, an outermost peripheral portion of the wafer cannot be polished or cleaned. Thus, it is necessary to polish the outermost peripheral portion of the wafer additionally with a device for edge polishing.

In contrast, a polishing device that holds the peripheral portion of the wafer with a plurality of rollers to rotate the wafer with rotation of the rollers has been known (see PTL 1). According to this device, the outermost peripheral portion of the wafer and a polishing head do not interfere with one another. Thus, a whole plane including the outermost peripheral portion of the wafer can be polished.

### CITATION LIST

### Patent Literature

PTL 1: Japanese Unexamined Patent Application Publication No. 2018-15890

### SUMMARY OF INVENTION

### Technical Problem

The device in PTL 1 can polish the whole plane of the wafer. However, a necessity for removing an unnecessary film and the like formed on a bevel portion of the wafer still remains A degree of polishing or cleaning of the peripheral portion of the plane of the wafer may be different from that of a central region of the wafer. Accordingly, when at least one of the bevel portion, a top edge portion, and a bottom edge portion can be processed while the plane of the wafer is being polished or cleaned, a throughput in a substrate processing process can be improved.

The present invention is to perform a process for a plane of a wafer and a process for at least one of a bevel portion, a top edge portion, and a bottom edge portion with a single device.

### Solution to Problem

According to one aspect of the present invention, there is provided a substrate processing device. This substrate processing device includes a substrate holder, a first processing head, and a second processing head. The substrate holder holds and rotates a substrate having a first plane and a second plane opposite to the first plane. The first processing head is configured to polish or clean the first plane of the substrate held on the substrate holder. The second processing head is configured to polish or clean at least one of a bevel portion and an edge portion of the substrate held on the substrate holder.

According to another aspect of the present invention, there is provided a substrate processing method. This substrate processing method includes a step of holding and rotating a substrate having a first plane and a second plane opposite to the first plane with a substrate holder, a step of polishing or cleaning the first plane of the substrate held on the substrate holder with a first processing head, and a step of polishing or cleaning at least one of a bevel portion and an edge portion of the substrate held on the substrate holder with a second processing head.

According to another aspect of the present invention, there is provided a storage medium that stores a program for causing a computer to execute a method for controlling a substrate processing device. This program causes the computer to execute a step of holding and rotating a substrate having a first plane and a second plane opposite to the first plane with a substrate holder, a step of polishing or cleaning the first plane of the substrate held on the substrate holder with a first processing head, and a step of polishing or cleaning at least one of a bevel portion and an edge portion of the substrate held on the substrate holder with a second processing head.

### BRIEF DESCRIPTION OF DRAWINGS

FIG. 1 is a schematic plan view of a substrate processing system including a substrate processing device according to the embodiment;

FIG. 2 is a schematic diagram of the substrate processing device;

FIG. 3 is a plan view illustrating a roller rotation mechanism in detail;

FIG. 4 is a bottom view of a first processing head;

FIG. 5 is a plan view illustrating an arrangement of the first processing head;

FIG. 6 is a block diagram illustrating a configuration of an operation control unit;

FIG. 7A is a cross-sectional view of a straight type substrate;

FIG. 7B is a cross-sectional view of a round type substrate;

FIG. 8A is a schematic plan view of the substrate processing device according to the embodiment;

FIG. 8B is a schematic side view of the substrate processing device according to the embodiment;

FIG. 9 is a flowchart illustrating a process of the substrate processing device;

FIG. 10A is a schematic side view of a substrate processing device according to another embodiment;

FIG. 10B is a schematic side view of the substrate processing device according to the other embodiment;

FIG. 10C is a schematic side view of the substrate processing device according to the other embodiment;

FIG. 11A is a side view of a substrate processing device according to yet another embodiment;

FIG. 11B is a side view of the substrate processing device according to yet another embodiment; and

FIG. 12 is a side view of the substrate processing device according to yet another embodiment.

### DESCRIPTION OF EMBODIMENTS

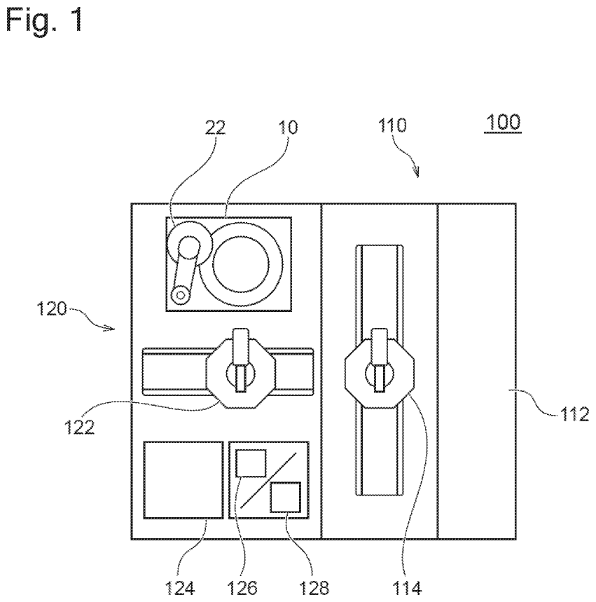

The following describes embodiments of the present invention with reference to the drawings. In the drawings described later, the identical reference numerals are assigned for the identical or equivalent elements, and therefore such elements will not be further elaborated here. FIG. 1 is a schematic plan view of a substrate processing system including a substrate processing device according to the embodiment. A substrate processing system 100 is divided into a loading and unloading unit 110 and a substrate processing unit 120 as a whole.

The loading and unloading unit 110 includes a front loading unit 112 and a first conveyance robot 114. The front loading unit 112 is configured to include an open cassette, a Standard Manufacturing Interface (SMIF) pod, or a Front Opening Unified Pod (FOUP). The SMIF and the FOUP are sealing containers that internally house a cassette housing a substrate such as a wafer and cover it with a partition wall to be able to keep an environment independent from an external space.

The first conveyance robot 114 is configured to be movable along an arranging direction of the cassette inside the front loading unit 112. The first conveyance robot 114 can access the cassette mounted on the front loading unit 112 to extract the substrate from the cassette.

The substrate processing unit 120 includes a second conveyance robot 122, a system controller 124, a cleaning unit 126, a drying unit 128, and a substrate processing device 10. The second conveyance robot 122 is configured to be movable in a horizontal direction. The system controller 124 is configured to control an operation of the whole substrate processing system. The cleaning unit 126 is configured to clean a polished substrate. The drying unit 128 is configured to dry the cleaned substrate. The cleaning unit 126 and the drying unit 128 may be arranged to overlap one another in a vertical direction. The substrate processing device 10 includes a first processing head 22 for polishing or cleaning the substrate.

The first conveyance robot 114 extracts the substrate from the cassette to convey it to the substrate processing device 10. The substrate processing device 10 polishes or cleans the received substrate. The substrate is extracted from the substrate processing device 10 and conveyed to the cleaning unit 126 by the second conveyance robot 122. In one embodiment, the cleaning unit 126 includes an upper roll sponge and a lower roll sponge that are arranged to sandwich the substrate. The cleaning unit 126 cleans both surfaces of the substrate with these roll sponges while supplying both surfaces of the substrate with a cleaning liquid. When the substrate is cleaned in the substrate processing device 10, the cleaning by the cleaning unit 126 is not necessary.

The substrate is conveyed to the drying unit 128 by the second conveyance robot 122. In one embodiment, the drying unit 128 performs spin drying by rotating the substrate at high speed. The dried substrate is returned to the cassette of the front loading unit 112 by the first conveyance robot 114. Thus, the substrate processing system 100 can execute a sequence of processes of the polishing, the cleaning, and the drying of the wafer.

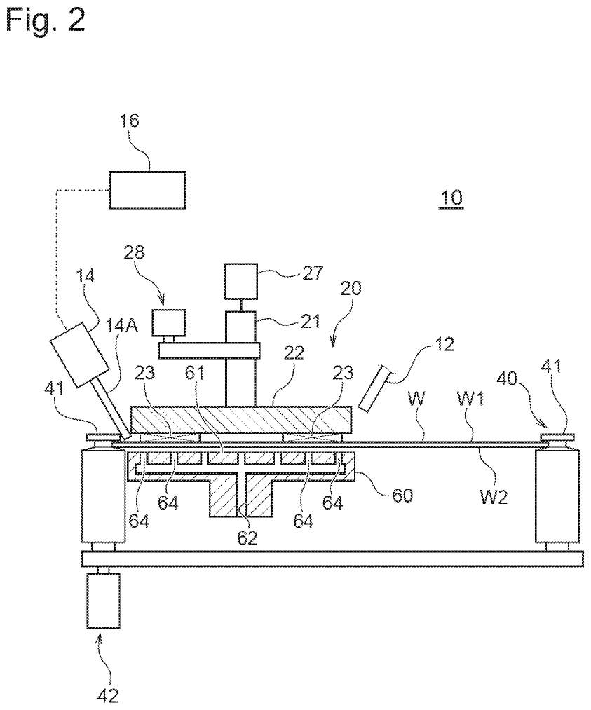

The following describes the substrate processing device 10 illustrated in FIG. 1 in detail. FIG. 2 is a schematic diagram of the substrate processing device 10. In FIG. 2, a second processing head 80, which will be described later, is not illustrated. As illustrated in FIG. 2, the substrate processing device 10 includes a substrate processing head assembly 20, a substrate holder 40, and a first static pressure supporting stage 60 (equivalent to an exemplary first substrate supporting portion). The substrate holder 40 is configured to hold and rotate a substrate W such as the wafer. The substrate processing head assembly 20 is configured to polish or clean a first plane W1 of the substrate W held on the substrate holder 40 to remove a foreign object or a scratch on the first plane W1. The first static pressure supporting stage 60 is configured to support a second plane W2 opposite to the first plane W1. The substrate processing head assembly 20 is arranged above the substrate W held on the substrate holder 40. The first static pressure supporting stage 60 is arranged below the substrate W held on the substrate holder 40. Specifically, the first static pressure supporting stage 60 is arranged in a position (equivalent to an exemplary first position) facing the first processing head 22 of the substrate processing head assembly 20 across the substrate W while the substrate processing head assembly 20 is polishing or cleaning the first plane W1.

In one embodiment, the first plane W1 of the substrate W is a back surface on which a device is not formed, of the substrate W, that is, a non-device surface, and the second plane W2 is a surface on which the device has been formed, that is, a device surface. In another embodiment, the first plane W1 of the substrate W is the device surface, and the second plane W2 of the substrate W is the back surface on which the device is not formed, of the substrate W. An exemplary back surface on which the device is not formed includes a silicon surface. In this embodiment, the substrate W is horizontally held on the substrate holder 40 in a state where its first plane W1 is up.

The substrate holder 40 includes a plurality of rollers 41, which are configured to contact a peripheral portion of the substrate W, and a roller rotation mechanism 42, which rotates these rollers 41 centering on respective axial centers. In this embodiment, four rollers 41 are disposed, but it is not limited to this. At least three or more rollers 41 can be disposed. The roller rotation mechanism 42 is configured to rotate the four rollers 41 in an identical direction and at an identical speed. In one embodiment, the roller rotation mechanism 42 includes a motor, a belt, a pulley, and the like. While the substrate processing head assembly 20 is polishing or cleaning the first plane W1 of the substrate W, the peripheral portion of the substrate W is horizontally held by the rollers 41, and rotation of the rollers 41 rotates the substrate W in a circumferential direction.

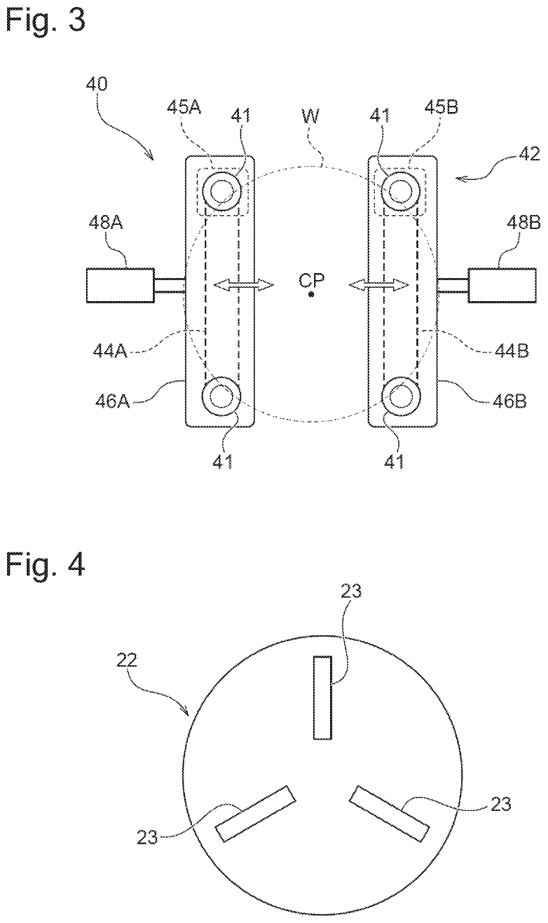

FIG. 3 is a plan view illustrating the roller rotation mechanism 42 in detail. The roller rotation mechanism 42 includes a first belt 44A, a first motor 45A, a first roller stand 46A, a second belt 44B, a second motor 45B, and a second roller stand 46B. The first belt 44A couples two (two on the left side in the drawing) of the four rollers 41. The first motor 45A is configured to be coupled to one of the two rollers 41 coupled by the first belt 44A to rotatably drive this roller 41. The first roller stand 46A rotatably supports the two rollers 41 coupled by the first belt 44A. The second belt 44B couples other two (two on the right side in the drawing) of the four rollers 41. The second motor 45B is coupled to one of the two rollers 41 coupled by the second belt 44B. The second roller stand 46B rotatably supports the two rollers 41 coupled by the second belt 44B.

The first motor 45A and the first belt 44A are arranged below the first roller stand 46A. The second motor 45B and the second belt 44B are arranged below the second roller stand 46B. The first motor 45A and the second motor 45B are secured to respective lower surfaces of the first roller stand 46A and the second roller stand 46B. Respective pulleys (not illustrated) are secured to lower portions of the four rollers 41. The first belt 44A is stretched between the pulleys secured to two of the four rollers 41. The second belt 44B is stretched between the pulleys secured to the other two rollers 41. The first motor 45A and the second motor 45B are configured to rotate at an identical speed and in an identical direction. Accordingly, the four rollers 41 can rotate at an identical speed and in an identical direction.

The roller rotation mechanism 42 further includes a first actuator 48A coupled to the first roller stand 46A and a second actuator 48B coupled to the second roller stand 46B. The first actuator 48A moves the two rollers 41 supported to the first roller stand 46A in a horizontal direction (an arrow direction in the drawing) to get close to or separate from the second roller stand 46B. Similarly, the second actuator 48B moves the other two rollers 41 supported to the second roller stand 46B in the horizontal direction (an arrow direction in the drawing) to get close to or separate from the first roller stand 46A. The first actuator 48A and the second actuator 48B can be configured from air cylinders, motor-driven actuators, or the like. In the embodiment illustrated in FIG. 3, the first actuator 48A and the second actuator 48B are configured from the air cylinders.

When the two pairs of rollers 41 move in directions getting close to one another, the substrate W is held by the four rollers 41. When the two pairs of rollers 41 move in directions separating from one another, the substrate W is released from the four rollers 41. In this embodiment, the four rollers 41 are disposed on the substrate holder 40. However, for example, three rollers 41 may be arranged at equal intervals having an angle of 120 degrees, and the actuators may be disposed on the respective rollers 41 one by one.

With reference to FIG. 2 again, a rinse liquid supply nozzle 12, which supplies the first plane W1 of the substrate W with a rinse liquid (for example, a pure water), is arranged above the substrate W held on the substrate holder 40. The rinse liquid supply nozzle 12 is connected to a rinse liquid supply source (not illustrated). The rinse liquid supply nozzle 12 is arranged facing the center of the substrate W. The rinse liquid is supplied to the center of the substrate W from the rinse liquid supply nozzle 12 to expand over the first plane WI of the substrate W with a centrifugal force of the rotating substrate W. The rinse liquid is preferably constantly supplied to the first plane W1 of the substrate W while the substrate W is being processed in the substrate processing device 10. This can reduce formation of a watermark on the first plane W1 of the substrate W.

As illustrated in FIG. 2, a particle counter 14 is arranged adjacent to the first processing head 22. The particle counter 14 is configured to include a suction nozzle 14A to suction the rinse liquid supplied to the first plane W1 of the substrate W, thus counting the number of particles contained in the rinse liquid. The suction nozzle 14A has a distal end that is arranged immediately above the first plane W1 of the substrate W held on the substrate holder 40 and outside a distal end of the rinse liquid supply nozzle 12 in a radial direction. Accordingly, the rinse liquid supplied approximately to the center of the first plane W1 of the substrate W from the rinse liquid supply nozzle 12 flows on the substrate W outward in the radial direction to contact a processing tool 23 of the first processing head 22, and then, a part of the rinse liquid is suctioned by the suction nozzle 14A. In this embodiment, the distal end of the suction nozzle 14A is close to the peripheral portion of the substrate W held on the substrate holder 40.

The particle counter 14 is connected to an operation control unit 16. The particle counter 14 transmits a data signal representing the number of particles contained in the rinse liquid to the operation control unit 16. The operation control unit 16 determines an ending point of the polishing or the cleaning of the first plane W1 of the substrate W based on the number of particles in the received data. Specifically, for example, the operation control unit 16 determines whether the number of particles in the received data is smaller than a predetermined threshold or not. When the operation control unit 16 determines that the number of particles in the received data is smaller than the predetermined threshold, the operation control unit 16 ends the polishing or the cleaning of the first plane W1.

The substrate processing head assembly 20 includes the first processing head 22 that polishes or cleans the first plane W1 of the substrate W held on the substrate holder 40 to remove the foreign object or the scratch from the first plane W1 of the substrate W. The first processing head 22 is coupled to a lower end of a head shaft 21 that extends in a vertical direction. The head shaft 21 is coupled to a head rotation mechanism 28. The head rotation mechanism 28 rotates the head shaft 21 centering on its shaft center. As a result, the first processing head 22 coupled to the head shaft 21 rotates centering on the shaft center of the head shaft 21.

Furthermore, the head shaft 21 has an upper end that is coupled to an air cylinder 27 configured to apply a downward load to the first processing head 22. The first processing head 22 includes at least one processing tool 23 for polishing or cleaning the first plane W1 of the substrate W. The first processing head 22 has a lower surface that is a processing surface configured from the processing tool 23. In one embodiment, the head rotation mechanism 28 includes a known configuration such as a motor, a belt, and a pulley.

In this embodiment, the processing tool 23 is configured from a polishing tape having one surface on which a polishing layer containing abrasive grains has been formed. The polishing tape has both ends that are held on two reels (not illustrated) arranged inside the first processing head 22, and a lower surface of the polishing tape extending between the two reels is configured to contact the first plane W1 of the substrate W. In one embodiment, the processing tool 23 may be a sponge, a nonwoven fabric, a foamed polyurethane, or a fixed abrasive grain. Corresponding to a purpose: whether the substrate W is cleaned or polished, a material of the processing tool 23 can be determined.

FIG. 4 is a bottom view of the first processing head 22. As illustrated in FIG. 4, in this embodiment, three processing tools 23 are disposed on the first processing head 22. The respective processing tools 23 extend in a radial direction of the first processing head 22 and arranged at equal intervals centering on an axial center of the first processing head 22. The first processing head 22, while rotating centering on its axial center, brings the processing tool 23 into contact with the first plane W1 of the substrate W to polish or clean the substrate W.

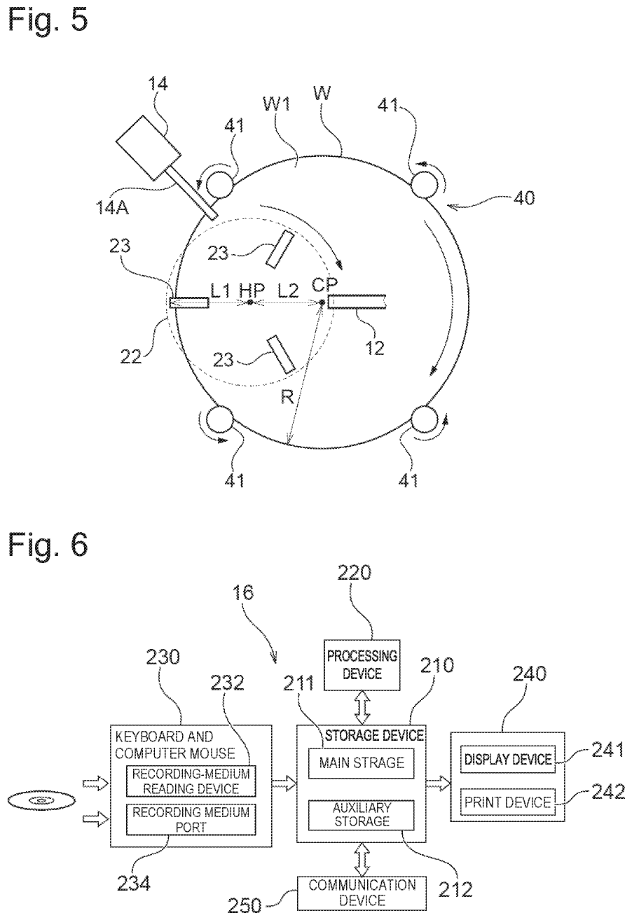

FIG. 5 is a plan view illustrating an arrangement of the first processing head 22. The plurality of respective rollers 41 are arranged around an axial center CP of the substrate holder 40 and positioned at an equal distance from the axial center CP of the substrate holder 40. When the substrate W is held by the plurality of rollers 41, a center point of the substrate W is on the axial center CP of the substrate holder 40.

The first processing head 22 has a diameter greater than a radius R of the substrate W. The first processing head 22 has an axial center HP that is deviated from the axial center CP of the substrate holder 40. Accordingly, the first processing head 22 is eccentric with respect to the substrate W held on the substrate holder 40. When a distance from the axial center HP of the first processing head 22 to an outermost edge portion of the processing tool 23 is defined as L1 and a distance from the axial center CP of the substrate holder 40 to the axial center HP of the first processing head 22 is defined as L2, a sum of the distance L1 and the distance L2 is longer than the radius R of the substrate W. Thereby, as illustrated in FIG. 5, when the first processing head 22 polishes the first plane W1 of the substrate W, a part of the processing tool 23 protrudes from the peripheral portion of the substrate W held by the rollers 41.

As seen from FIG. 5, while the first processing head 22 is rotating, the processing tool 23 can contact from the center to the outermost of the first plane W1 of the substrate W. Accordingly, the processing tool 23 can polish the whole first plane W1 of the substrate W. During the polishing of the first plane W1 of the substrate W, all the rollers 41 rotate centering on the respective axial centers, while the positions of these rollers 41 are fixed. Accordingly, even if a part of the processing tool 23 protrudes from the peripheral portion of the substrate W, the rollers 41 do not contact the first processing head 22.

With reference to FIG. 2 again, the first static pressure supporting stage 60 is configured to support the second plane W2 of the substrate W held by the rollers 41. In this embodiment, the first static pressure supporting stage 60 is configured to support the substrate W with a fluid by bringing the fluid into contact with the second plane W2 of the substrate W held by the rollers 41. The first static pressure supporting stage 60 has a substrate support surface 61 close to the second plane W2 of the substrate W held by the rollers 41. Furthermore, the first static pressure supporting stage 60 includes a plurality of fluid injection ports 64 formed on the substrate support surface 61 and a fluid supply passage 62 connected to the fluid injection ports 64. The substrate support surface 61 of the first static pressure supporting stage 60 is slightly separated from the second plane W2 of the substrate W. The fluid supply passage 62 is connected to a fluid supply source (not illustrated). The substrate support surface 61 in this embodiment has a circular shape, but may have a square or another shape.

The first static pressure supporting stage 60 supplies the plurality of fluid injection ports 64 with the fluid (for example, a liquid such as the pure water) through the fluid supply passage 62, thus filling a space between the substrate support surface 61 and the second plane W2 of the substrate W with the fluid. The substrate W is supported by the fluid that exists between the substrate support surface 61 and the second plane W2 of the substrate W. A clearance with the first static pressure supporting stage 60 is, for example, 50 μm to 500 μm, thus contactlessly keeping the substrate W and the first static pressure supporting stage 60.

The first static pressure supporting stage 60 can support the second plane W2 of the substrate W in a contactless state via the fluid. Accordingly, when the device has been formed on the second plane W2 of the substrate W, the first static pressure supporting stage 60 can support the substrate W without breaking the device. As the fluid used by the first static pressure supporting stage 60, a liquid such as the pure water as an incompressible fluid, or a gas as a compressible fluid such as air or nitrogen may be used.

The lower surface (the processing surface) of the first processing head 22 and the substrate support surface 61 of the first static pressure supporting stage 60 are preferably concentrically arranged. The lower surface of the first processing head 22 and the substrate support surface 61 of the first static pressure supporting stage 60 are arranged to sandwich the substrate W. The load applied to the substrate W from the first processing head 22 is supported by the first static pressure supporting stage 60 from immediately below the first processing head 22. Accordingly, the first processing head 22 can apply a large load to the first plane W1 of the substrate W while reducing bend of the substrate W supported by a fluid pressure.

FIG. 6 is a block diagram illustrating a configuration of the operation control unit 16. The operation control unit 16 includes a storage device 210, a processing device 220, an input device 230, an output device 240, and a communication device 250. The storage device 210 stores programs, data, and the like. The processing device 220 is a central processing unit (CPU) that executes computing in accordance with the program stored in the storage device 210. The input device 230 inputs data, a program, and various kinds of information to the storage device 210. The output device 240 outputs a process result or processed data. The communication device 250 connects to a network such as the Internet.

The storage device 210 includes a main storage 211 that the processing device 220 can access and an auxiliary storage 212 that stores the data and the program. The main storage 211 is, for example, a random access memory (RAM). The auxiliary storage 212 is a storage device such as a hard disk drive (HDD) or a solid state drive (SSD).

The input device 230 includes a keyboard and a computer mouse. Furthermore, the input device 230 includes a recording-medium reading device 232 for reading data from a recording medium, and a recording medium port 234 to which the recording medium is connected. The recording medium is a computer readable recording medium as a non-transitory material object, for example, an optical disk (for example, a CD-ROM and a DVD-ROM) and a semiconductor memory (for example, a USB flash drive and a memory card). The recording-medium reading device 232 is, for example, an optical drive such as a CD drive and a DVD drive, and a card reader. The recording medium port 234 is, for example, a USB terminal. At least one of the program and the data recorded in the recording medium is introduced into the operation control unit 16 via the input device 230 and then, stored in the auxiliary storage 212 of the storage device 210. The output device 240 includes a display device 241 and a print device 242.

The operation control unit 16 operates in accordance with the program electrically stored in the storage device 210. The operation control unit 16 is electrically connected to the rinse liquid supply nozzle 12, the particle counter 14, the substrate processing head assembly 20, the substrate holder 40, and the first static pressure supporting stage 60, which are illustrated in FIG. 2, to control their operation.

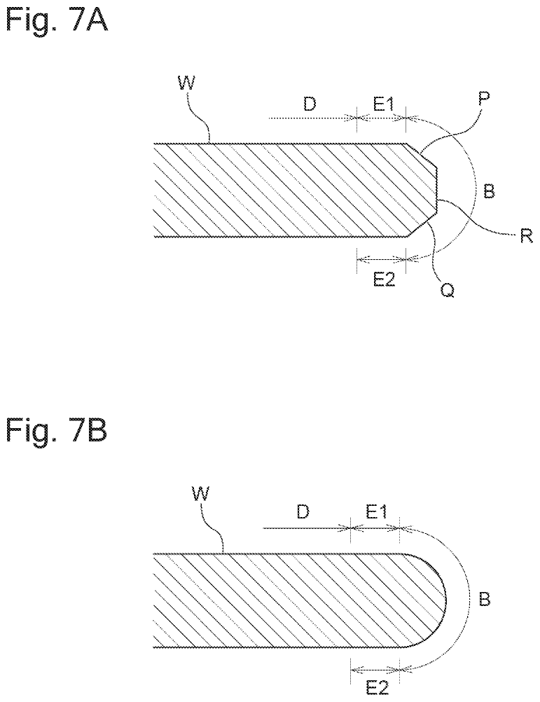

The following describes names of parts of the substrate W polished or cleaned in this embodiment. FIG. 7A is a cross-sectional view of, what is called, a straight type substrate W. FIG. 7B is a cross-sectional view of, what is called, a round type substrate W. In the substrate W in FIG. 7A, a bevel portion B is an outermost peripheral surface of the substrate W excluding a planar portion of the substrate W. The bevel portion B is configured from an upper inclined portion (an upper bevel portion) P, a lower inclined portion (a lower bevel portion) Q, and a side portion (an apex) R. In the substrate W in FIG. 7B, a bevel portion B is a part having a curved cross-sectional surface that constitutes an outermost peripheral surface of the substrate W excluding a planar portion of the substrate W.

In the substrate W illustrated in FIG. 7A and FIG. 7B, a top edge portion, which is a region positioned radially inside the bevel portion B, is a flat portion E1 positioned radially outside a region on which the device is formed. The flat portion E1 may include a region on which the device that will not be a product has been formed. A bottom edge portion, which is positioned on a plane on a side opposite to the top edge portion, is a flat portion E2 positioned radially inside the bevel portion B. Similarly, the flat portion E2 may include a region on which the device that will not be a product has been formed. In this description, the top edge portion and the bottom edge portion are sometimes collectively referred to as an edge portion. In this description, the peripheral portion of the substrate W is formed of the bevel portion B, the top edge portion, and the bottom edge portion.

In this embodiment, the substrate processing head assembly 20 illustrated in FIG. 2 can polish the whole first plane W1 of the substrate W. However, when the process on at least one of the bevel portion B, the top edge portion, and the bottom edge portion can be performed while the first plane W1 of the substrate W is being polished or cleaned, a throughput of a substrate processing process can be improved. Therefore, the substrate processing device 10 according to the embodiment includes a second processing head separately from the first processing head 22 to perform the process on at least one of the bevel portion B, the top edge portion, and the bottom edge portion.

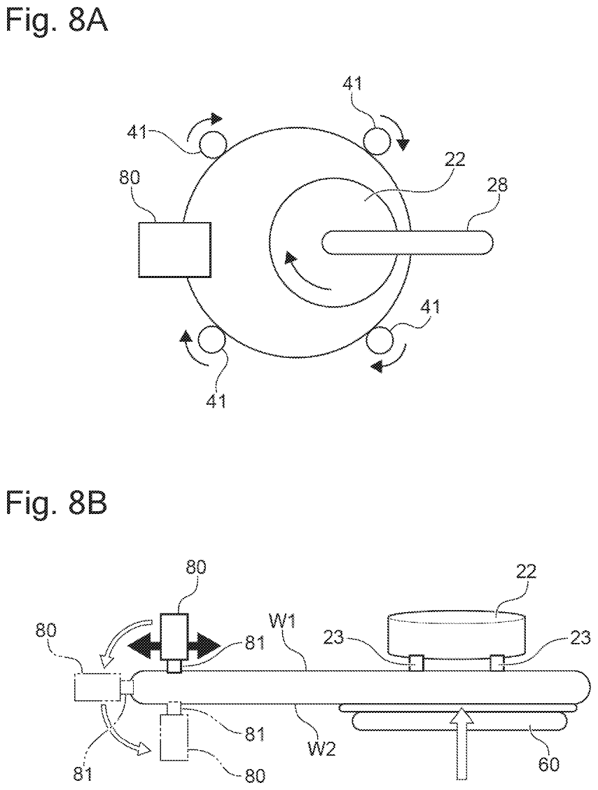

FIG. 8A illustrates a schematic plan view of the substrate processing device 10 according to the embodiment. FIG. 8B illustrates a schematic side view of the substrate processing device 10 according to the embodiment. In FIG. 8A and FIG. 8B, a part of the respective components illustrated in FIG. 2 is omitted. As illustrated in FIG. 8A, the substrate W is rotatably held by the rollers 41 such that the first plane W1 faces up. In FIG. 8B, the rollers 41 are omitted. The first processing head 22 causes the processing tool 23 to abut on the first plane W1 of the substrate W to polish or clean the first plane W1 of the substrate W. At this time, as illustrated in FIG. 8B, the first static pressure supporting stage 60 is arranged in the position (equivalent to an exemplary first position) facing the first processing head 22 across the substrate W. FIG. 8A and FIG. 8B illustrate the simplified first processing head 22. Thus, it is illustrated such that the processing tool 23 does not reach the center of the substrate W in the radial direction and the peripheral portion of the substrate W. However, as illustrated in FIG. 5, it is preferable to be configured such that the processing tool 23 reaches the center in the radial direction and the peripheral portion of the substrate W. The first processing head 22 may be configured movable in the horizontal direction so that the processing tool 23 can polish or clean the whole surface of the first plane W1 of the substrate W.

The substrate processing device 10 further includes the second processing head 80 configured to polish or clean at least one of the bevel portion B and the edge portion of the substrate W held by the rollers 41. The second processing head 80 includes a processing tool 81 to cause the processing tool 81 to abut on at least one of the bevel portion B and the edge portion of the substrate W, thus polishing or cleaning at least one of the bevel portion B and the edge portion of the substrate W. As the processing tool 81, for example, a polishing tape, a sponge, a nonwoven fabric, a foamed polyurethane, a fixed abrasive grain, or the like can be employed. As illustrated in FIG. 8B, the second processing head 80 is configured movable between the bevel portion B and the edge portion with a head moving mechanism (not illustrated).

The substrate processing device 10 is configured to press the second processing head 80 to the bevel portion B or the edge portion of the substrate W with an air cylinder or the like (not illustrated). This air cylinder or the like (not illustrated) is communicatively connected to the operation control unit 16 illustrated in FIG. 2. The operation control unit 16 controls the air cylinder 27 and the air cylinder or the like (not illustrated) such that a force with which the air cylinder 27 presses the first processing head 22 to the substrate W is different from a force with which the air cylinder or the like (not illustrated) presses the second processing head 80 to the substrate W. In other words, the operation control unit 16 controls the first processing head 22 and the second processing head 80 such that the load applied to the substrate W by the first processing head 22 is different from a load applied to the substrate W by the second processing head 80. This can polish or clean the first plane W1 of the substrate W and the bevel portion B or the edge portion such that appropriate loads are applied to the respective positions.

When the second processing head 80 polishes or cleans the edge portion (the top edge portion in FIG. 8B) of the first plane W1, a region polished or cleaned by the first processing head 22 preferably at least partially overlaps a region polished or cleaned by the second processing head 80. This can eliminate a region that is not polished or cleaned in the first plane W1.

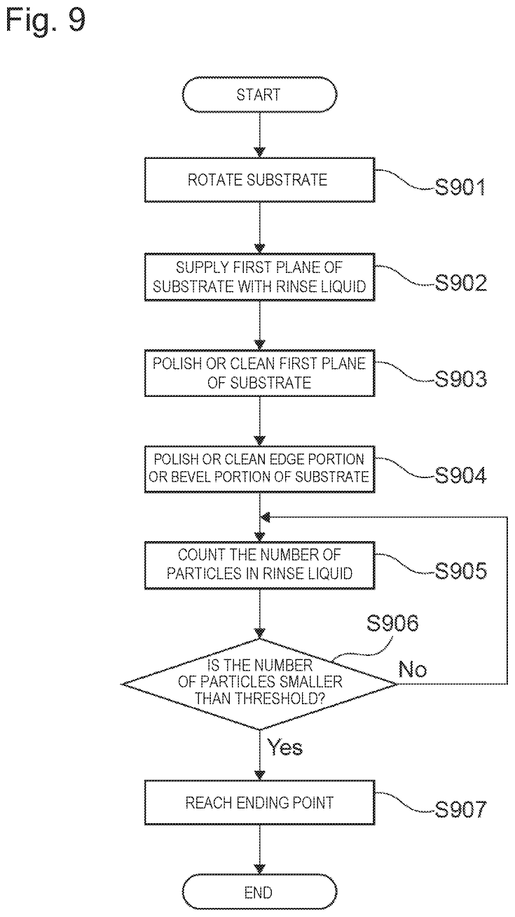

The following describes operation of the substrate processing device 10. FIG. 9 is a flowchart illustrating a process of the substrate processing device 10. First, the substrate W to be processed is rotated by the rollers 41 of the substrate holder 40 in a state where the first plane W1 is up (Step S901). The fluid (for example, a liquid such as the pure water) is injected from the first static pressure supporting stage 60 to fill a space between the first static pressure supporting stage 60 and the second plane W2 of the substrate W with the fluid. The substrate W is supported by the fluid flowing through between the first static pressure supporting stage 60 and the second plane W2 of the substrate W.

The rinse liquid supply nozzle 12 illustrated in FIG. 2 supplies the center of the substrate W with the rinse liquid to expand the rinse liquid over the first plane W1 of the substrate W with the centrifugal force of the rotating substrate W (Step S902). The head rotation mechanism 28 rotates the first processing head 22 centering on its axial center HP in a direction identical to the rotation direction of the substrate W. Then, the air cylinder 27 presses the rotating first processing head 22 to the first plane W1 of the substrate W. The first processing head 22 causes the processing tool 23 to abut on the first plane W1 of the substrate W in a state where the rinse liquid exists on the first plane W1 of the substrate W to polish or clean the first plane W1 (Step S903).

Similarly, in the state where the rinse liquid exists on the first plane W1 of the substrate W, the second processing head 80 causes the processing tool 81 to abut on the edge portion or the bevel portion B of the substrate W to polish or clean the edge portion or the bevel portion B (Step S904). Step S903 and Step S904 may be simultaneously performed, or the process in Step S904 may be performed prior to the process in Step S903. In one embodiment, prior to the polishing or the cleaning by the first processing head 22, the second processing head 80 polishes or cleans the bevel portion B. Firstly performing the polishing or the cleaning of the bevel portion B can reduce attachment to and accumulation in the rollers 41 of the foreign objects or the like of the bevel portion B. As a result, the rollers 41 can stably rotate the substrate W in polishing or cleaning a subsequent first plane W1.

Subsequently, during the polishing of the first plane W1 of the substrate W and the edge portion or the bevel portion B, the particle counter 14 suctions the rinse liquid to count the number of particles contained in the rinse liquid (Step S905). Many of the particles contained in the rinse liquid are the foreign objects removed from the first plane W1 of the substrate W. Accordingly, the number of particles contained in the rinse liquid is substantially proportionate to an amount of the foreign objects removed from the first plane W1 of the substrate W. The operation control unit 16 determines whether the number of particles is smaller than a threshold or not (Step S906). When the number of particles is determined to be smaller than the threshold (Step S907, Yes), the operation control unit 16 determines that the polishing or the cleaning of the first plane W1 has reached the ending point to end the polishing or the cleaning by the first processing head 22 (Step S907). When the number of particles is equal to or more than the threshold (Step S907, No), Step S905 and Step S906 are repeated.

In one embodiment, when the polishing or the cleaning by the first processing head 22 ends (Step S907), the second processing head 80 can end the polishing or the cleaning assuming that the polishing or the cleaning of the bevel portion B or the edge portion also has reached the ending point. In another embodiment, the second processing head 80 may polish or clean the bevel portion B or the edge portion for a predetermined period.

During the polishing or the cleaning of the first plane W1 by the first processing head 22, the second processing head 80 may polish or clean only the top edge portion or the bottom edge portion or may polish or clean only the bevel portion B. During the polishing or the cleaning of the first plane W1 by the first processing head 22, the second processing head 80 may move between the top edge portion, the bevel portion B, and the bottom edge portion to polish or clean all of these parts.

In the substrate processing device 10 illustrated in FIG. 8A and FIG. 8B, as one example, when the first processing head 22 polishes the first plane W1 as a surface on which the device is not formed to make the substrate W thin, what is called, wafer chipping caused by an R shape of an outer peripheral portion of the substrate W may occur. Therefore, the second processing head 80 can polish the bottom edge portion of the second plane W2 simultaneously, alternately, or continuously with the polishing by the first processing head 22 to remove an R-shaped portion of the outer peripheral portion of the substrate W. That is, the substrate processing device 10 illustrated in FIG. 8A and FIG. 8B can perform, what is called, edge trimming simultaneously, alternately, or continuously with the polishing of the first plane W1 of the substrate W.

A program for causing the operation control unit 16 to execute the respective steps illustrated in FIG. 9 may be recorded in a computer-readable non-transitory recording medium to be provided to the operation control unit 16 via the recording medium. Alternatively, this program may be provided to the operation control unit 16 via a communication network such as the Internet. The operation control unit 16 also controls a process of a substrate processing device 10 in another embodiment, which will be described later, and a program for causing the operation control unit 16 to execute this process also may be recorded in the computer-readable recording medium.

As described above, the substrate processing device 10 according to the embodiment includes the first processing head 22 and the second processing head 80. Thus, the process on the plane of the wafer and the process on at least one of the bevel portion B, the top edge portion, and the bottom edge portion can be performed with a single device. Eventually, the process on the wafer plane and the process on at least one of the bevel portion B, the top edge portion, and the bottom edge portion can be simultaneously performed to improve the throughput of the substrate processing process. It is not necessary to additionally prepare a device that performs the process on at least one of the bevel portion B, the top edge portion, and the bottom edge portion, thus ensuring reduction in footprint of the device.

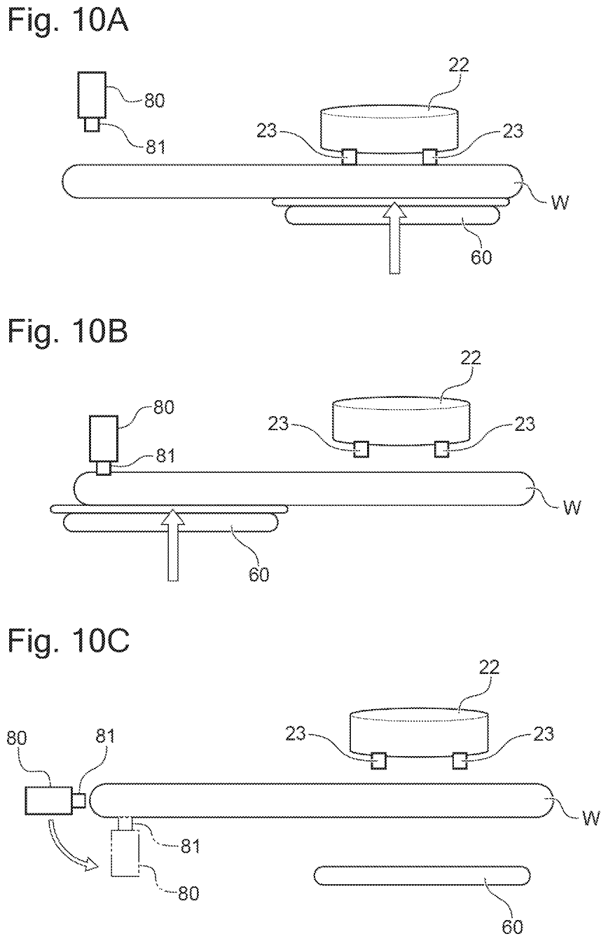

The following describes a substrate processing device 10 according to another embodiment. FIG. 10A, FIG. 10B, and FIG. 10C illustrate schematic side views of a substrate processing device 10 according to the other embodiment. In FIG. 10A to FIG. 10C, a part of the respective components illustrated in FIG. 2 is omitted. The omitted part has a configuration similar to that of the substrate processing device 10 illustrated in FIG. 1 to FIG. 9. FIG. 10A to FIG. 10C illustrate the simplified first processing head 22. Thus, it is illustrated such that the processing tool 23 does not reach the center of the substrate W in the radial direction and the peripheral portion of the substrate W. However, as illustrated in FIG. 5, it is preferable to be configured such that the processing tool 23 reaches the center in the radial direction and the peripheral portion of the substrate W.

In the substrate processing device 10 illustrated in FIG. 10A to FIG. 10C, the polishing or the cleaning by the first processing head 22 and the second processing head 80 is alternatingly or continuously performed, and the first static pressure supporting stage 60 is movably configured. As illustrated in FIG. 10A, the first processing head 22 causes the processing tool 23 to abut on the first plane W1 of the substrate W to polish or clean the first plane W1 of the substrate W. At this time, as illustrated in FIG. 10A, the first static pressure supporting stage 60 is arranged in the position facing the first processing head 22 across the substrate W.

After the polishing or the cleaning of the first plane W1 by the first processing head 22 ends or halts, the second processing head 80 polishes or cleans the substrate W. At this time, as illustrated in FIG. 10B, the first static pressure supporting stage 60 moves to a position (equivalent to an exemplary second position) facing the second processing head 80 across the substrate W with a moving mechanism (not illustrated). In the example in FIG. 10B, the second processing head 80 is polishing or cleaning the top edge portion of the substrate W. Thus, the first static pressure supporting stage 60 is supporting the second plane W2 of the substrate W. When the second processing head 80 polishes or cleans the bevel portion B of the substrate W, the first static pressure supporting stage 60 can move to any retracted position without interference with the second processing head 80. This can reduce interference by the first static pressure supporting stage 60 with the second processing head 80 when the second processing head 80 polishes or cleans the bevel portion B.

As illustrated in FIG. 10C, when the second processing head 80 polishes or cleans the bottom edge portion of the substrate W, the first static pressure supporting stage 60 moves to a retracted position without interference with the second processing head 80. This can reduce interference by the first static pressure supporting stage 60 with the second processing head 80 when the second processing head 80 polishes or cleans the bottom edge portion. In one embodiment, when the second processing head 80 polishes or cleans the bottom edge portion of the substrate W, the first static pressure supporting stage 60 may move to a side of the first plane W1 to be arranged in the position (equivalent to an exemplary second position) facing the second processing head 80 across the substrate W.

As described above, according to the substrate processing device 10 illustrated in FIG. 10A to FIG. 10C, the first static pressure supporting stage 60 is movably configured. This ensures support of the substrate W by the single first static pressure supporting stage 60 while the substrate W is being polished or cleaned by the first processing head 22 and while the substrate W is being polished or cleaned by the second processing head 80. In the substrate processing device 10 illustrated in FIG. 10A to FIG. 10C, the polishing or the cleaning by the second processing head 80 may be performed prior to the polishing or the cleaning by the first processing head 22.

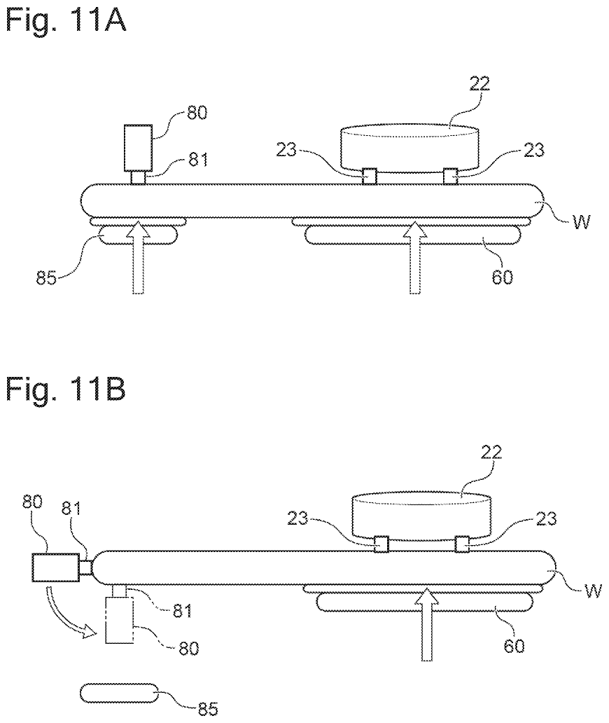

FIG. 11A and FIG. 11B are side views of a substrate processing device 10 according to yet another embodiment. In FIG. 11A and FIG. 11B, a part of the respective components illustrated in FIG. 2 is omitted. The omitted part has a configuration similar to that of the substrate processing device 10 illustrated in FIG. 1 to FIG. 9. FIG. 11A and FIG. 11B illustrate the simplified first processing head 22. Thus, it is illustrated such that the processing tool 23 does not reach the center of the substrate W in the radial direction and the peripheral portion of the substrate W. However, as illustrated in FIG. 5, it is preferable to be configured such that the processing tool 23 reaches the center in the radial direction and the peripheral portion of the substrate W.

The substrate processing device 10 illustrated in FIG. 11A and FIG. 11B includes a second static pressure supporting stage 85 configured to support the first plane W1 or the second plane W2. The second static pressure supporting stage 85, which has a structure similar to that of the first static pressure supporting stage 60, is movably configured. As illustrated in FIG. 11A, the first processing head 22 causes the processing tool 23 to abut on the first plane W1 of the substrate W to polish or clean the first plane WI of the substrate W. At this time, as illustrated in FIG. 11A, the first static pressure supporting stage 60 is arranged in the position facing the first processing head 22 across the substrate W. The second processing head 80 causes the processing tool 81 to abut on the top edge portion of the first plane W1 of the substrate W to polish or clean the top edge portion of the first plane W1. At this time, as illustrated in FIG. 11A, the second static pressure supporting stage 85 is arranged in the position facing the second processing head 80 across the substrate W. In the substrate processing device 10 illustrated in FIG. 11A and FIG. 11B, the polishing or the cleaning by the first processing head 22 and the second processing head 80 is simultaneously, alternately, or continuously performed.

As illustrated in FIG. 11B, when the second processing head 80 polishes or cleans the bevel portion B or the bottom edge portion of the substrate W, the second static pressure supporting stage 85 can move to any retracted position without interference with the second processing head 80. This can reduce interference by the second static pressure supporting stage 85 with the second processing head 80 when the second processing head 80 polishes or cleans the bevel portion B or the bottom edge portion.

As described above, the substrate processing device 10 illustrated in FIG. 11A and FIG. 11B includes the first static pressure supporting stage 60 and the second static pressure supporting stage 85. This ensures the support of the substrate W by the first static pressure supporting stage 60 and the second static pressure supporting stage 85 when the first processing head 22 and the second processing head 80 polish or clean the substrate W respectively. As a result, the first processing head 22 and the second processing head 80 can simultaneously apply large loads to the substrate W while reducing the bend of the substrate W supported by the fluid pressure.

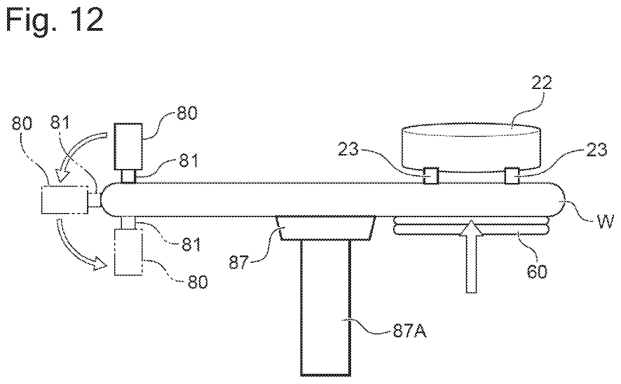

FIG. 12 is a side view of a substrate processing device 10 according to yet another embodiment. In FIG. 12, a part of the respective components illustrated in FIG. 2 is omitted. The omitted part has a configuration similar to that of the substrate processing device 10 illustrated in FIG. 1 to FIG. 9. FIG. 12 illustrates the simplified first processing head 22. Thus, it is illustrated such that the processing tool 23 does not reach the center of the substrate W in the radial direction and the peripheral portion of the substrate W. However, as illustrated in FIG. 5, it is preferable to be configured such that the processing tool 23 reaches the center in the radial direction and the peripheral portion of the substrate W.

The substrate processing device 10 illustrated in FIG. 12 includes a chuck portion 87 configured to suction and hold the second plane W2 of the substrate W. The chuck portion 87 is configured to circumferentially rotate centering on a shaft center of a rotation shaft 87A to circumferentially rotate the suctioned and held substrate W. As illustrated in the drawing, the chuck portion 87 holds the substrate W such that the edge portion of the second plane W2 of the substrate W projects outside the chuck portion 87 in the radial direction. In other words, the chuck portion 87 has a diameter designed to have a size such that the edge portion of the second plane W2 of the substrate W is exposed. The chuck portion 87 may has, for example, known vacuum suction structure or electrostatic suction structure.

In the substrate processing device 10 illustrated in FIG. 12, the chuck portion 87 contacts the second plane W2 of the substrate W. Thus, the second plane W2 is the back surface on which the device is not formed, of the substrate W. Accordingly, the first processing head 22 is configured to polish or clean the first plane W1 as the surface on which the device has been formed. As illustrated in FIG. 12, the first processing head 22 causes the processing tool 23 to abut on the first plane W1 of the substrate W to polish or clean the first plane W1 of the substrate W. At this time, as illustrated in FIG. 12, the first static pressure supporting stage 60 is arranged in the position facing the first processing head 22 across the substrate W. The second processing head 80 can cause the processing tool 81 to abut on the top edge portion of the first plane W1 of the substrate W, the bottom edge portion of the second plane W2, or the bevel portion B to polish or clean at least one of them. In the substrate processing device 10 illustrated in FIG. 12, the polishing or the cleaning by the first processing head 22 and the second processing head 80 is simultaneously, alternately, or continuously performed. The substrate processing device 10 illustrated in FIG. 12 may include the second static pressure supporting stage 85 illustrated in FIG. 11A and FIG. 11B.

As described above, according to the substrate processing device 10 illustrated in FIG. 12, the first processing head 22 and the second processing head 80 can polish or clean the substrate W whose back surface is held on the chuck portion 87.

The embodiments of the present invention have been described above in order to facilitate understanding of the present invention without limiting the present invention. The present invention can be changed or improved without departing from the gist thereof, and of course, the equivalents of the present invention are included in the present invention. It is possible to arbitrarily combine or omit respective components according to claims and description in a range in which at least a part of the above-described problems can be solved, or a range in which at least a part of the effects can be exhibited.

The following describes some aspects disclosed by this description.

According to a first aspect, there is provided a substrate processing device. This substrate processing device includes a substrate holder that holds and rotates a substrate, a first processing head that processes a first plane of the substrate held on the substrate holder, and a second processing head that processes a peripheral portion of the substrate held on the substrate holder.

According to a second aspect, in the substrate processing device of the first aspect, the second processing head is configured to process a bevel portion of the substrate.

According to a third aspect, the substrate processing device of the first aspect or the second aspect includes a control device configured to control the first processing head and the second processing head such that a force with which the first processing head is pressed to the substrate is different from a force with which the second processing head is pressed to the substrate.

According to a fourth aspect, the substrate processing device of any of the first aspect to the third aspect includes a first substrate supporting portion configured to support a second plane as a plane opposite to the first plane of the substrate. The first substrate supporting portion is arranged in a first position facing the first processing head across the substrate while the first processing head is processing the first plane.

According to a fifth aspect, in the substrate processing device of the fourth aspect, the second processing head is configured to process an edge portion of the substrate, and the first substrate supporting portion is arranged in a second position facing the second processing head across the substrate while the second processing head is processing the edge portion of the first plane.

According to a sixth aspect, in the substrate processing device of the fifth aspect, the first substrate supporting portion is arranged in a retracted position without interference with the second processing head while the second processing head is processing a bevel portion of the substrate or the edge portion of the second plane.

According to a seventh aspect, the substrate processing device of the third aspect or the fourth aspect includes a second substrate supporting portion configured to support the first plane or a second plane as a plane opposite to the first plane of the substrate. The second substrate supporting portion is arranged in a position facing the second processing head across the substrate while the second processing head is processing an edge portion of the substrate.

According to an eighth aspect, in the substrate processing device of the seventh aspect, the second substrate supporting portion is arranged in a retracted position without interference with the second processing head while the second processing head is processing a bevel portion of the substrate or the edge portion of the second plane.

According to a ninth aspect, in the substrate processing device of any of the first aspect to the eighth aspect, the substrate holder includes at least three rollers configured to contact the peripheral portion of the substrate, and the rollers are configured rotatable centering on axial centers of the respective rollers.

According to a tenth aspect, in the substrate processing device of any of the first aspect to the eighth aspect, the substrate holder includes a chuck portion that suctions a second plane as a plane opposite to the first plane of the substrate, and the chuck portion is configured to hold the substrate such that an edge portion of the second plane of the substrate projects outside the chuck portion in a radial direction.

According to an eleventh aspect, in the substrate processing device of any of the first aspect to the tenth aspect, the second processing head is configured to process an edge portion of the first plane of the substrate, and a region processed by the first processing head at least partially overlaps a region processed by the second processing head.

According to a twelfth aspect, there is provided a substrate processing method. This substrate processing method includes holding and rotating a substrate with a substrate holder, processing a first plane of the substrate held on the substrate holder with a first processing head, and processing a peripheral portion of the substrate held on the substrate holder with a second processing head.

According to a thirteenth aspect, the substrate processing method of the twelfth aspect includes processing an edge portion of the substrate held on the substrate holder with the second processing head.

According to a fourteenth aspect, in the substrate processing method of the twelfth aspect or the thirteenth aspect, a force with which the first processing head is pressed to the substrate and a force with which the second processing head is pressed to the substrate are mutually different.

According to a fifteenth aspect, the substrate processing method of any of the twelfth aspect to the fourteenth aspect includes arranging a first substrate supporting portion in a first position facing the first processing head across the substrate while the first processing head is processing the first plane.

According to a sixteenth aspect, the substrate processing method of the fifteenth aspect includes arranging the first substrate supporting portion in a second position facing the second processing head across the substrate while the second processing head is processing an edge portion of the substrate.

According to a seventeenth aspect, the substrate processing method of the sixteenth aspect includes arranging the first substrate supporting portion in a retracted position without interference with the second processing head while the second processing head is processing a bevel portion of the substrate or the edge portion of a second plane opposite to the first plane.

According to an eighteenth aspect, the substrate processing method of the fifteenth aspect includes arranging a second substrate supporting portion in a second position facing the second processing head across the substrate while the second processing head is processing an edge portion of the substrate.

According to a nineteenth aspect, the substrate processing method of the eighteenth aspect includes arranging the second substrate supporting portion in a retracted position without interference with the second processing head while the second processing head is processing a bevel portion of the substrate or the edge portion of a second plane opposite to the first plane.

According to a twentieth aspect, in the substrate processing method of any of the twelfth aspect to the nineteenth aspect, the holding and rotating the substrate includes bringing at least three rollers into contact with the peripheral portion of the substrate to rotate the rollers centering on axial centers of the respective rollers.

According to a twenty-first aspect, in the substrate processing method of any of the twelfth aspect to the nineteenth aspect, the holding and rotating the substrate includes suctioning the second plane of the substrate with a chuck portion, and an edge portion of the second plane opposite to the first plane of the substrate is configured to project outside the chuck portion in a radial direction.

According to a twenty-second aspect, in the substrate processing method of any of the twelfth aspect to the twenty-first aspect, a region processed by the second processing head at least partially overlaps a region processed by the first processing head.

According to a twenty-third aspect, there is provided a storage medium that stores a program for causing a computer of a substrate processing device to execute a method for controlling the substrate processing device. This program causes the computer to execute holding and rotating a substrate with a substrate holder, processing a first plane of the substrate held on the substrate holder with a first processing head, and processing a peripheral portion of the substrate held on the substrate holder with a second processing head.

### REFERENCE SIGNS LIST

10 . . . substrate processing device

16 . . . operation control unit

20 . . . substrate processing head assembly

22 . . . first processing head

23 . . . processing tool

40 . . . substrate holder

41 . . . roller

60 . . . first static pressure supporting stage

80 . . . second processing head

81 . . . processing tool

85 . . . second static pressure supporting stage

87 . . . chuck portion

B . . . bevel portion

W1 . . . first plane

W2 . . . second plane

W . . . substrate

What is claimed is:

1. A substrate processing device comprising:
a substrate holder that holds and rotates a substrate;
a first processing head that processes a first plane of the substrate held on the substrate holder; and
a second processing head that processes a peripheral portion of the substrate held on the substrate holder.

2. The substrate processing device according to claim 1, wherein
the second processing head is configured to process a bevel portion of the substrate.

3. The substrate processing device according to claim 1, further comprising
a control device configured to control the first processing head and the second processing head such that a force with which the first processing head is pressed to the substrate is different from a force with which the second processing head is pressed to the substrate.

4. The substrate processing device according to claim 1, further comprising
a first substrate supporting portion configured to support a second plane opposite to the first plane of the substrate, wherein
the first substrate supporting portion is arranged in a first position facing the first processing head across the substrate while the first processing head is processing the first plane.

5. The substrate processing device according to claim 4, wherein
the second processing head is configured to process an edge portion of the substrate, and
the first substrate supporting portion is arranged in a second position facing the second processing head across the substrate while the second processing head is processing the edge portion of the first plane.

6. The substrate processing device according to claim 5, wherein
the first substrate supporting portion is arranged in a retracted position without interference with the second processing head while the second processing head is processing a bevel portion of the substrate or the edge portion of the second plane.

7. The substrate processing device according to claim 3, further comprising
a second substrate supporting portion configured to support the first plane or a second plane opposite to the first plane of the substrate, wherein
the second substrate supporting portion is arranged in a position facing the second processing head across the substrate while the second processing head is processing an edge portion of the substrate.

8. The substrate processing device according to claim 7, wherein
the second substrate supporting portion is arranged in a retracted position without interference with the second processing head while the second processing head is processing a bevel portion of the substrate or the edge portion of the second plane.

9. The substrate processing device according to claim 1, wherein
the substrate holder includes at least three rollers configured to contact the peripheral portion of the substrate, and
the rollers are configured rotatable centering on axial centers of the respective rollers.

10. The substrate processing device according to claim 1, wherein
the substrate holder includes a chuck portion that suctions a second plane opposite to the first plane of the substrate, and
the chuck portion is configured to hold the substrate such that an edge portion of the second plane of the substrate projects outside the chuck portion in a radial direction.

11. The substrate processing device according to claim 1, wherein
the second processing head is configured to process an edge portion of the first plane of the substrate, and
a region processed by the first processing head at least partially overlaps a region processed by the second processing head.

12. A substrate processing method comprising:
holding and rotating a substrate with a substrate holder;
processing a first plane of the substrate held on the substrate holder with a first processing head; and
processing a peripheral portion of the substrate held on the substrate holder with a second processing head.

13. The substrate processing method according to claim 12, further comprising
processing an edge portion of the substrate held on the substrate holder with the second processing head.

14. The substrate processing method according to claim 12, wherein
a force with which the first processing head is pressed to the substrate and a force with which the second processing head is pressed to the substrate are mutually different.

15. The substrate processing method according to claim 12, further comprising
arranging a first substrate supporting portion in a first position facing the first processing head across the substrate while the first processing head is processing the first plane.

16. The substrate processing method according to claim 15, further comprising
arranging the first substrate supporting portion in a second position facing the second processing head across the substrate while the second processing head is processing an edge portion of the substrate.

17. The substrate processing method according to claim 16, further comprising
arranging the first substrate supporting portion in a retracted position without interference with the second processing head while the second processing head is processing a bevel portion of the substrate or the edge portion of a second plane opposite to the first plane.

18. The substrate processing method according to claim 15, further comprising
arranging a second substrate supporting portion in a second position facing the second processing head across the substrate while the second processing head is processing an edge portion of the substrate.

19. The substrate processing method according to claim 18, further comprising
arranging the second substrate supporting portion in a retracted position without interference with the second processing head while the second processing head is processing a bevel portion of the substrate or the edge portion of a second plane opposite to the first plane.

20. The substrate processing method according to claim 12, wherein
the holding and rotating the substrate includes bringing at least three rollers into contact with the peripheral portion of the substrate to rotate the rollers centering on axial centers of the respective rollers.

21. The substrate processing device according to claim 12, wherein
the holding and rotating the substrate includes suctioning a second plane opposite to the first plane of the substrate with a chuck portion, and
an edge portion of the second plane of the substrate is configured to project outside the chuck portion in a radial direction.

22. The substrate processing device according to claim 12, wherein
a region processed by the second processing head at least partially overlaps a region processed by the first processing head.

23. A non-transitory storage medium that stores a program for causing a computer of a substrate processing device to execute a method for controlling the substrate processing device, the program causes the computer to execute:
holding and rotating a substrate with a substrate holder;
processing a first plane of the substrate held on the substrate holder with a first processing head; and
processing a peripheral portion of the substrate held on the substrate holder with a second processing head.
